(19) United States
(12) Patent Application Publication
(10) Pub. No.: US 2014/0294201 A1
(43) Pub. Date: Oct. 2, 2014

(54) AUDIO CALIBRATION SYSTEM AND METHOD

(71) Applicant: THOMSON LICENSING, Issy de Moulineaux (FR)

(72) Inventors: Ronald Douglas Johnson, Westfield, IN (US); Mark Alan Schultz, Billings, MO (US)

(21) Appl. No.: 14/235,205

(22) PCT Filed: Jul. 26, 2012
(86) PCT No.: PCT/US2012/048271

§ 371 Date: Jun. 19, 2014

Related U.S. Application Data
(60) Provisional application No. 61/512,538, filed on Jul. 28, 2011.

(51) Int. Cl. H03G 99/00

(52) U.S. Cl. CPC H03G 99/00
USPC 381/107

(57) ABSTRACT

Described herein is an audio calibration system and method that determines optimum placement and/or operating conditions of speakers for an entertainment system. The system receives an audio signal and transmits the audio signal to a speaker. A recordation of an emanated audio signal from each speaker is made. The system performs a sliding window fast Fourier transform (FFT) comparison of the recorded audio signal temporally and volumetrically with the audio signal. A time delay for each speaker is shifted so that each of the plurality of speakers is synchronized. The individual volumes are then compared for each speaker and are adjusted to collectively match. The method can align and move the convergence point of multiple audio sources. Time differences are measured with respect to a microphone as a function of position. The method uses any audio data and functions with background noise in real time.

### CROSS REFERENCE TO RELATED APPLICATIONS

This application claims the benefit of U.S. provisional application No. 61/512,538, filed Jul. 28, 2011, the contents of which are hereby incorporated by reference herein.

### FIELD OF INVENTION

This application is related to calibration of audio systems.

### BACKGROUND

Audio systems having a plurality of speakers can have different speakers that are not synchronized with one another, not synchronized with video and have poor volume balance. As such, a need exists for a device and/or method for optimizing the delays and volumes in an audio system that has a plurality of speakers.

When a user installs a home theater or home audio system all of the speakers are generally set to use the same delay. In a perfect square room with speakers placed exactly in the corners, the audio sweet spot would be in the middle of the room. Rooms are rarely ideal though. Volume and delays can be calibrated using a microphone placed in the individual audio paths to align the time that the audio reaches a point in the room. The volume from the individual speakers can also be determined and adjusted. This will work for different shapes of rooms and even for rooms that have no walls on one or more sides.

Calibrations of systems have been performed by ear and with hand held dB meters. In many cases only the audio volume can be adjusted. Also, previous system calibration efforts to adjust delays for the back set of speakers have required individual control. In other words, each speaker in a system has to be isolated or run by itself one after another for proper calibration to avoid contamination. Moreover, when each speaker is calibrated or tested, there can be no background noise.

### SUMMARY

Described herein is an audio calibration system and method that determines preferred placement and/or operating conditions for a given set of speakers used for an entertainment system. The system receives an audio signal and transmits the audio signal to a speaker. A recordation of an emanated audio signal from each speaker is made. The system performs a sliding window fast Fourier transform (FFT) comparison of the recorded audio signal temporally and volumetrically with the audio signal. A time delay for each speaker is shifted so that each of the plurality of speakers is synchronized. The individual volumes are then compared for each speaker and the individual volumes of each speaker are adjusted to collectively match. The method can align and move the convergence point of multiple audio sources. Time differences associated with each speaker are measured with respect to a microphone as a function of position. The method can use any audio data and function with unrelated background noise in real time.

A specific embodiment involves a method for calibrating audio for a plurality of speakers, comprising: receiving a sample audio signal; transmitting the sample audio signal to at least one speaker; recording the sample audio signal from each speaker individually; performing a fast Fourier (FFT) comparison of recorded sample audio signal temporally and volumetrically with the sample audio signal; shifting a time delay for each speaker so that each of the plurality of speakers is synchronized; comparing individual volumes of each speaker; and adjusting individual volumes of each speaker to collectively match. An FFT profile can be generated for each sample audio signal sent to the at least one speaker. The FFT comparison can include sliding an individual FFT profile across a FFT profile of recorded audio from the plurality of speakers; and determining correlation coefficients as the individual FFT profile slides across the FFT profile of recorded audio from the plurality of speakers; wherein the time delay is based on the correlation coefficients. The FFT profile can be generated for the recorded sample audio signal. In the method, the time delay can account for delay differences present between an individual FFT profile and a FFT profile of recorded audio from the plurality of speakers.

Another specific embodiment involves an audio calibration system for calibrating a plurality of speakers, comprising: a recording device configured to record a sample audio signal emanating from a speaker; an audio calibration module configured to perform an FFT comparison of each recorded sample audio signal in terms of time and volume to the sample audio signal; the audio calibration module is configured to shift a time delay for each speaker so that the plurality of speakers is synchronized; and the audio calibration module is configured to compare individual volumes of each speaker or the audio calibration module is configured to adjust individual volumes of each speaker to match collectively. A FFT profile can be generated for each sample audio signal sent to the at least one speaker. The audio calibration module can be configured to slide an individual FFT profile across a FFT profile of recorded audio from the plurality of speakers and determine correlation coefficients as the individual FFT profile slides across the FFT profile of recorded audio from the plurality of speakers. The time delay can be based on the correlation coefficients and the FFT profile can be generated for the recorded sample audio signal. The time delay can account for delay differences present between an individual FFT profile and a FFT profile of recorded audio from the plurality of speakers.

Another embodiment can be for an audio calibration module for calibrating a plurality of speakers, comprising: an audio calibration module configured to perform an FFT comparison of a recorded sample audio signal in terms of time and volume to a sample audio signal; the audio calibration module is configured to shift a time delay for each speaker so that the plurality of speakers is synchronized; the audio calibration module is configured to compare individual volumes of each speaker; and the audio calibration module is configured to adjust individual volumes of each speaker to match collectively. An FFT profile can be generated for each sample audio signal sent to the at least one speaker, wherein the audio calibration module can be configured to slide an individual FFT profile across a FFT profile of recorded audio from the plurality of speakers and determine correlation coefficients as the individual FFT profile slides across the FFT profile of recorded audio from the plurality of speakers.

### BRIEF DESCRIPTION OF THE DRAWINGS

A more detailed understanding can be had from the following description, given by way of example in conjunction with the accompanying drawings wherein:

FIG. 1 is an example flowchart of a method for audio calibration;

FIG. 2 is an example block diagram of a receiving device; and

FIG. 3 is an example block diagram of an audio system with an audio calibration system;

FIGS. 4A-4D show example fast Fourier transform (FFT) images/profiles from a sound source with respect to each speaker shown in FIG. 3;

FIG. 5 shows an example FFT image/profile of captured audio that was played from the speakers in FIG. 3 and has an audio signature shown in FIG. 4;

FIG. 6 shows an example FFT image/profile signature for a speaker in FIG. 3 being slid across the FFT image/profile of the captured audio of FIG. 5; and

FIG. 7 shows an example audio energy captured by the microphone in FIG. 3.

### DETAILED DESCRIPTION

It is to be understood that the figures and descriptions of embodiments have been simplified to illustrate elements that are relevant for a clear understanding, while eliminating, for the purpose of clarity, many other elements. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein.

Described herein is an audio calibration system and method that determines the preferred placement and/or operating conditions of speakers for an entertainment system that has a plurality of speakers. The system can use any audio source and is not dependent on test audios. In general, the method can use a sliding window fast Fourier transform (FFT) to align and even move the convergence point of multiple audio sources. Time differences associated with each speaker are measured with respect to a microphone as a function of position. The method uses the sliding window FFT to calibrate using any audio data or test data and further permits the calibration to proceed in environments in which there can be unrelated background noise in real time. Using the sliding window FFT, appropriate delays for individual speakers can be obtained and implemented.

In general, an audio calibration system receives some test or original audio and determines an individual FFT profile of the audio to be sent to each speaker. The system transmits the test or original audio signal to one or more speakers at a time and records the test or original audio signal from the speaker(s). A FFT comparison of the recorded test or original audio signal to the test/original audio is performed in terms of time and volume. A correlation coefficient analysis is implemented that involves performing correlation calculations as the individual FFT profiles slide across the FFT profile generated from the recorded audio from all the speakers. The time delay for each speaker is shifted so that the speakers are each synchronized with one another based on the result of the correlation coefficient analysis. The individual volumes of each speaker are compared and are adjusted to match one another. By using a sliding window FFT, the measured audio can be correlated to the sent audio with proper delays. The measured time difference is fed back in a control loop to program the needed delays. This can be done once or in a continuous loop to continuously adjust the sweet spot to the location of the microphone as it moves around.

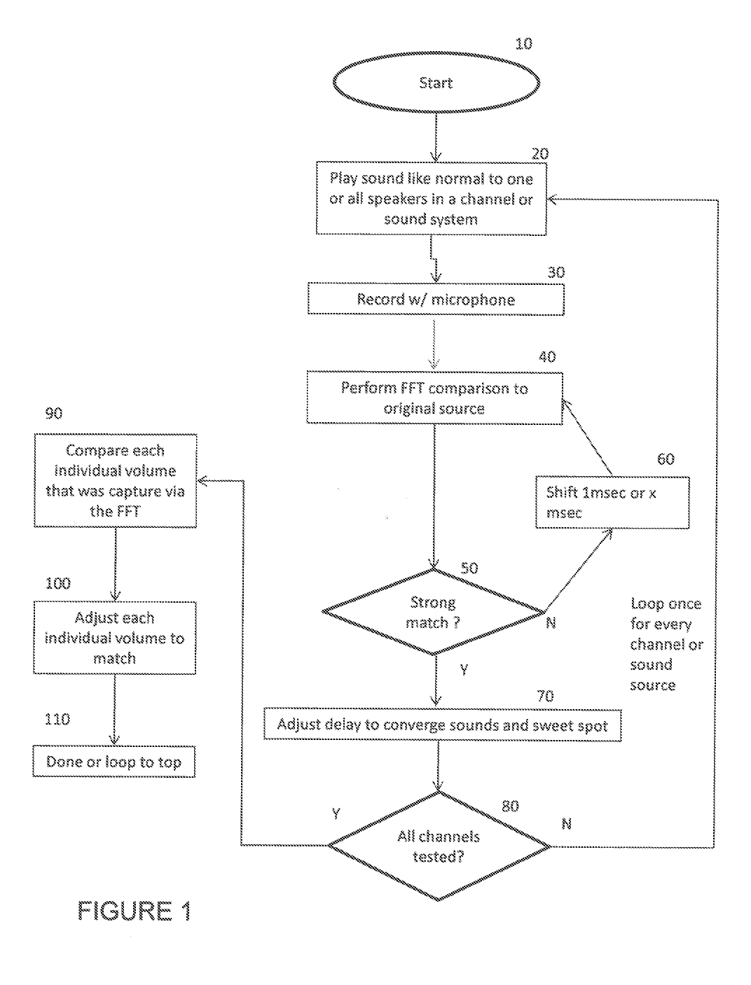

FIG. 1 shows an example flow chart for calibrating an audio system. This can be performed by a dedicated module, for example, an audio calibration module, or an external processing unit. A user initiates calibration by playing a sample audio signal which can be a test or original audio signal (10) and transmits the sample audio signal to at least one or all speakers (20). The individual FFT profiles can be obtained for the audio sent to each speaker. The audio from at least one speaker is then recorded with a recording device such as a microphone (30). The microphone can be part of the audio calibration system.

A FFT algorithm or program can be used to characterize the recorded audio in terms of time and volume and compare the recorded audio to the sample audio to get a delay value and volume (40). A FFT profile can be generated from the recorded audio such that the individual FFT profiles can be slid across the FFT profile of the captured or recorded audio to determine the temporal positional relationships of the audio from the different speakers. The FFT algorithm or program can be implemented in an audio calibration module or device of the audio calibration system.

If the recorded audio has some large delay with respect to the sample audio (50, “no” path), then shift the audio for a speaker by a predetermined or given time (60). For example, the time shift can be in 1 millisecond increments. The comparison loop (40-60) can be performed until the delay is not large. If the recorded audio has no large delay with respect to the sample audio (50, “yes” path), shift the audio for one speaker to match the delay of the others (70). If more speakers need to be tested (80, “no” path), then proceed to record the audio of the next speaker (20) and repeat the process for the next speaker. That is, the process can be looped once for every channel or sound source, as applicable. If no other speakers need to be tested (80, “yes” path), then compare the individual volumes that were captured using the FFT algorithm for each of the speaker(s) (90). If needed and as applicable, adjust the individual volumes for each of the speaker(s) to match each other (100). The process is performed for each speaker until complete (110).

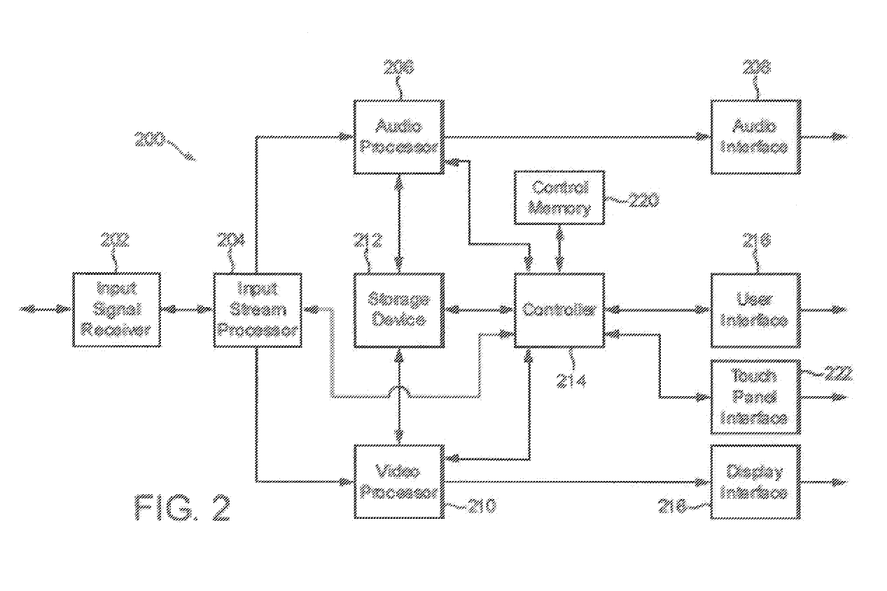

FIG. 2 is an example block diagram of a receiving device 200. The receiving device 200 can perform the method of FIG. 1 as described herein and can be included as part of a gateway device, modem, set top box, or other similar communications device. The device 200 can also be incorporated into other systems including an audio device or a display device. In either case, other components can be included.

Content is received by an input signal receiver 202. The input signal receiver 202 can be one of several known receiver circuits used for receiving, demodulation, and decoding signals provided over one of the several possible networks including over the air, cable, satellite, Ethernet, fiber and phone line networks. The desired input signal can be selected and retrieved by the input signal receiver 202 based on user input provided through a control interface or touch panel interface 222. The touch panel interface 222 can include an interface for a touch screen device and can also be adapted to interface to a cellular phone, a tablet, a mouse, a high end remote, iPad® or the like.

The decoded output signal from the input signal receiver 202 is provided to an input stream processor 204. The input stream processor 204 performs the final signal selection and processing. This can include separation of the video content from the audio content for the content stream. The audio content is provided to an audio processor 206 for conversion from the received format, such as compressed digital signal, to an analog waveform signal. The analog waveform signal is provided to an audio interface 208 and further to the display device or audio amplifier (not shown). Alternatively, the audio interface 208 can provide a digital signal to an audio output device or display device using a High-Definition Multimedia Interface (HDMI) cable or alternate audio interface such as via a Sony/Philips Digital Interconnect Format (SPDIF). The audio interface 208 can also include amplifiers for driving one more sets of speakers. The audio processor 206 also performs any necessary conversion for the storage of the audio signals in a storage device 212.

The video output from the input stream processor 204 is provided to a video processor 210. The video signal can be one of several formats. The video processor 210 provides, as necessary a conversion of the video content, based on the input signal format. The video processor 210 also performs any necessary conversion for the storage of the video signals in the storage device 212.

As stated, storage device 212 stores audio and video content received at the input. The storage device 212 allows later retrieval and playback of the content under the control of a controller 214 and also based on commands, e.g., navigation instructions such as fast-forward (FF) and rewind (Rew), received from a user interface 216 and/or touch panel interface 222. The storage device 212 can be a hard disk drive, one or more large capacity integrated electronic memories, such as static RAM (SRAM), or dynamic RAM (DRAM), or can be an interchangeable optical disk storage system such as a compact disc (CD) drive or digital video disc (DVD) drive.

The converted video signal, from the video processor 210, either originating from the input or from the storage device 212, is provided to the display interface 218. The display interface 218 further provides the display signal to a display device. The display interface 218 can be an analog signal interface such as red-green-blue (RGB) or can be a digital interface such as HDMI. It is to be appreciated that the display interface 218 will generate the various screens for presenting the search results in a three dimensional grid as will be described in more detail below.

The controller 214 is interconnected via a bus to several of the components of the device 200, including the input stream processor 204, audio processor 206, video processor 210, storage device 212, and a user interface 216. The controller 214 manages the conversion process for converting the input stream signal into a signal for storage on the storage device 212 or for display. The controller 214 also manages the retrieval and playback of stored content. Furthermore, as will be described below, the controller 214 performs searching of content and the creation and adjusting of the grid display representing the content, either stored or to be delivered via delivery networks.

The controller 214 is further coupled to control memory 220 for storing information and instruction code for controller 214. Control memory 220 can be, for example, volatile or non-volatile memory, including random access memory (RAM), static RAM (SRAM), dynamic RAM (DRAM), read only memory (ROM), programmable ROM (PROM), flash memory, electronically programmable ROM (EPROM), electronically erasable programmable ROM (EEPROM), and the like. Control memory 220 can store instructions for controller 214. Control memory 220 can also store a database of elements, such as graphic elements containing content. The database can be stored as a pattern of graphic elements.

Alternatively, the control memory 220 can store the graphic elements in identified or grouped memory locations and use an access or location table to identify the memory locations for the various portions of information related to the graphic elements. Further, the implementation of the control memory 220 can include several possible embodiments, such as a single memory device or, alternatively, more than one memory circuit communicatively connected or coupled together to form a shared or common memory. Still further, the control memory 220 can be included with other circuitry, such as portions of a bus communications circuitry, in a larger circuit.

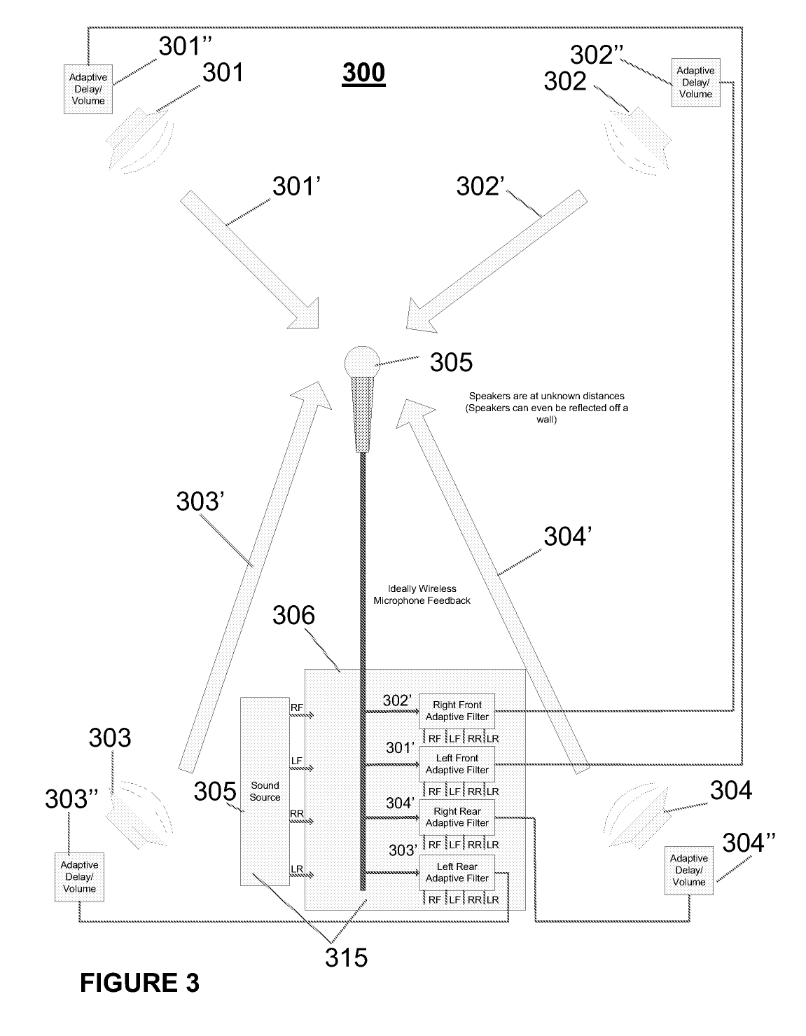

The user interface 216 also includes an interface for a microphone. The interface 216 can be a wired or wireless interface, allowing for the reception of the audio signal for use in the present embodiment. For example, the microphone can be microphone 310 as shown in FIG. 3, which is used for audio reception from the speakers in the room and is fed to the audio calibration module or other processing device. As described herein, the audio outputs of the microphone or receiving device are being modified to optimize the sound within the room.

FIG. 3 is an audio system 300 which includes four speakers 301, 302, 303, and 304 and corresponding audio 301′, 302′, 303′, and 304′ shown with respect to a receiver or microphone 310 of an audio calibration system 315. The audio calibration system 315 includes an audio calibration module or control and analysis system 306 that is connected to an audio source signal generator 305. The audio source signal generator 305 provides test audio or original audio. The audio calibration module or control and analysis system 306 receives the audio from the generator 305 and relays the audio to the appropriate speakers 301, 302, 303, and 304.

The audio calibration module or control and analysis system 306 includes a delay and volume control component 301″′, 302″′, 303″′, and 304″′, (i.e., Left Front Adaptive Filter, Right Front Adaptive Filter, Left Rear Adaptive Filter and Right Rear Adaptive Filter), that provides a signal to an adaptive delay and/or volume control means 301″, 302″, 303″, and 304″ for each speaker 301, 302, 303, and 304 which individually provides audio delay or volume adjustment to the individual speakers 301, 302, 303, and 304 to cause the calibration. The calibration can include finding a convergence point of the speaker system when the speakers 301, 302, 303, and 304 are operating under a certain set of operating conditions, adjusting audio delays so the audio from the speakers is in a desired phase relationship, and adjusting audio delays so that the audio from the speakers is in synchronization with the video. This ensures that sounds correspond to actions on a screen or have the proper or desired volume balance. The audio calibration module or control and analysis system 306 can be adapted to generate an FFT profile of the individual audio distributed to each speaker 301, 302, 303, and 304.

In an embodiment, applicable parts or sections of the audio system 300 can be implemented in part by the audio processor 206, controller 214, audio interface 208, storage device 212, user interface 216 and control memory 220. In another embodiment, the audio system 300 can be implemented by the audio processor 206 and in this latter case, there would also be a provision to include a microphone or audio receiving device (not shown). The microphone or audio receiving device is used as the feedback source signal for optimizing the audio as described herein.

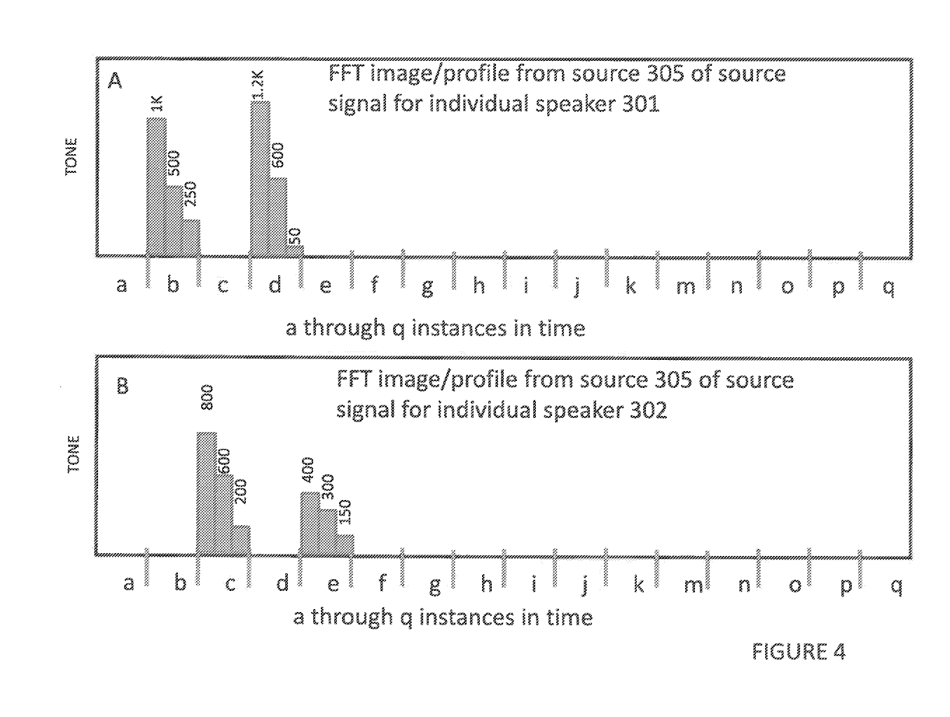

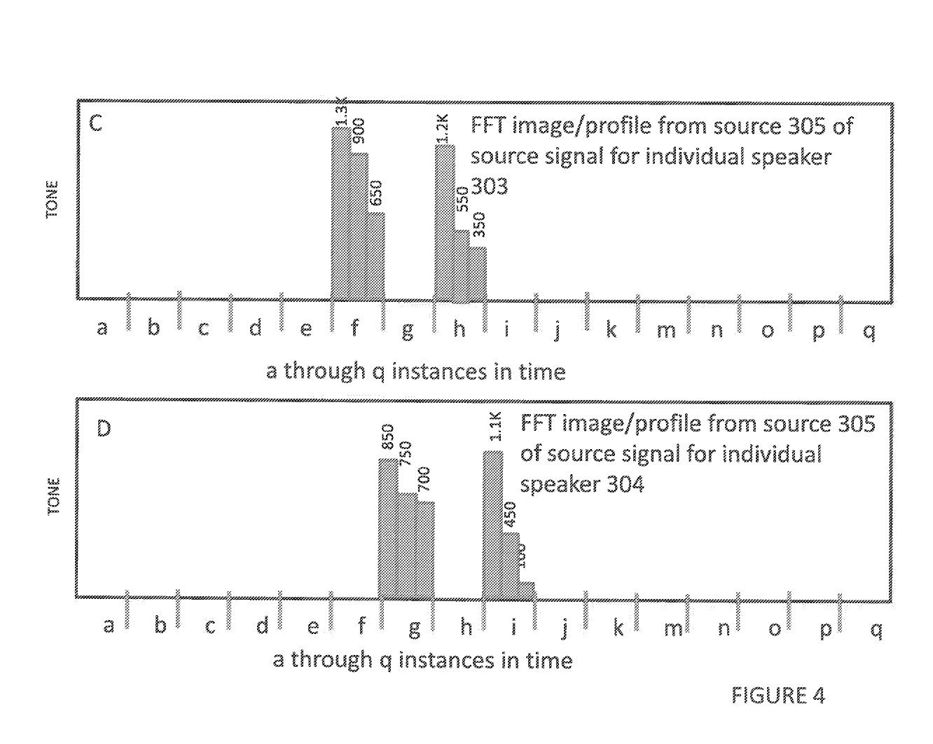

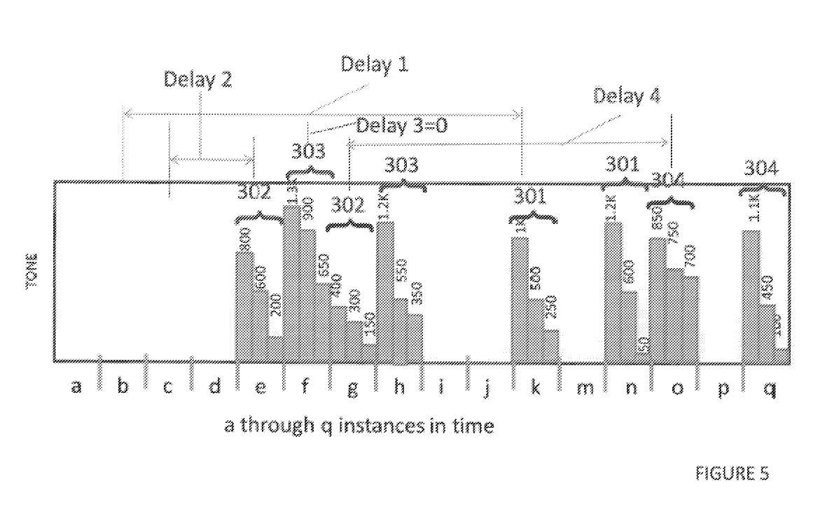

FIGS. 4A-4D and 5 show examples of applying the sliding window FFT to an audio signal for audio calibration. FIGS. 4A-4D show an individual FFT profile of the source signals to each of the individual channels/speakers. For purposes of illustration, the audio to each speaker is shown as being two instantaneous bursts of sound separated by some pause and the time frame of the burst is considered the desired timing for the individual audio. FIG. 4A shows an example FFT image/profile from sound source 305 with respect to speaker 301. FIG. 4B shows an example FFT image/profile from sound source 305 with respect to speaker 302. FIG. 4C shows an example FFT image/profile from sound source 305 with respect to speaker 303. FIG. 4D shows an example FFT image/profile from sound source 305 with respect to speaker 304.

FIG. 5 shows a real time FFT of all of the audio captured from the speakers 301, 302, 303, and 304 in FIG. 3. Although in the examples, there are two time intervals, (i.e., audio bursts), shown for the signal of each speaker, the first interval can be used for the delay information. The first burst can be used as a signature for cross correlation in which one can use a product-moment type correlation analysis.

The example FFT image/profile of the captured audio has an audio signature matching that in FIG. 4. In particular, the individual speakers 301, 302, 303, and 304 each have their own delays 1-4. The delays can be associated with how the signal is being relayed or transmitted in the video/audio system and the position/location of the speakers and microphone. At this point, the individual speaker controls can be changed or adjusted to change the individual resultant delays to some desired values which can, for example, match the video or/and match the speakers to each other. In FIG. 5, the delay 1 value corresponds to speaker 301 of FIG. 4A, the delay 2 value corresponds to speaker 302 of FIG. 4B, the delay 3 value corresponds to speaker 303 of FIG. 4C, (in this case it is zero because the image/profile from the captured audio corresponds temporarily or exactly with the image/profile image from the source 305), and the delay 4 value corresponds to speaker 304 of FIG. 4D.

Referring to FIGS. 4A-4D and 5, it can seen that it is possible to slide this signature along the continuous spectrum from the microphone and get a cross-correlation function that indicates the level of delay. For example, in FIG. 5, if one slides the signature for speaker 301 in FIG. 4A across FIG. 5, the correlation coefficient will be zero at interval b. As the signature is dragged across to the right, there can be some non-zero values due to signal capture from the other speakers. At time interval k the correlation should be 1 or very close to 1. If all the signals, (i.e., individual FFT profiles), are the same frequency and/or are the same over a long time, the individual speakers can have to be played separately. If the individual audio for different speakers have differences, (particularly in tones or tone combinations), the technique is powerful for real signals without requiring special test signals so that the consumer never notices that this is occurring for calibration purposes.

From the illustrations in the FIGS. 3-5, the source 305 knows what is being sent to each speaker 301, 302, 303, and 304 and performs an FFT on each channel to generate a source signal. This can be considered the signature or reference signal for each channel which in the frequency domain would be represented by a collection of tones, (which can be any number). In the examples of FIGS. 4A-4D and 5, there are only three simultaneous tones, for example, at each moment in time for all of the speakers. The number can be variable depending on the application. In fact, it is advantageous that there is more than one tone and further advantageous to have unique tone values for each speaker during the calibration to ensure that the correlations will be very low during a sliding operation and only very high when the given signature is aligned with the captured audio packet from the given speaker. The cross correlation is a sliding FFT image in time with a similar FFT image. The differences are measured as the sliding occurs and the best match of the signals represents the delay between the signals.

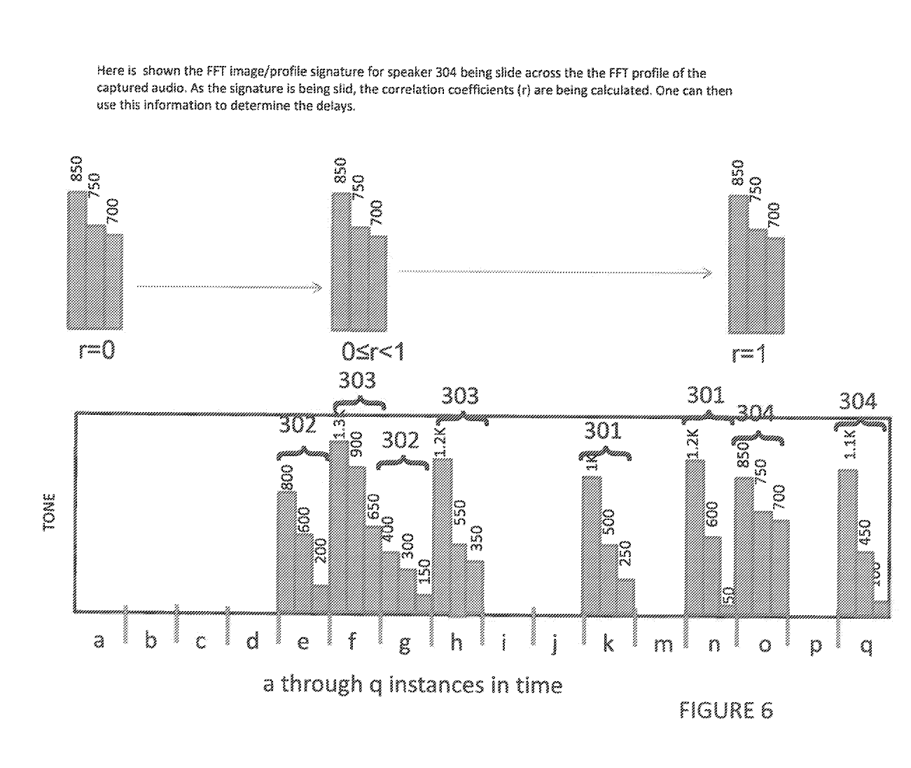

FIG. 6 shows an example FFT image/profile signature for a speaker in FIG. 3 being slid across the FFT image/profile of the captured audio of FIG. 5. As the signature slides across the captured audio, the correlation coefficients (r) are being calculated. This information can then be used to determine the delays.

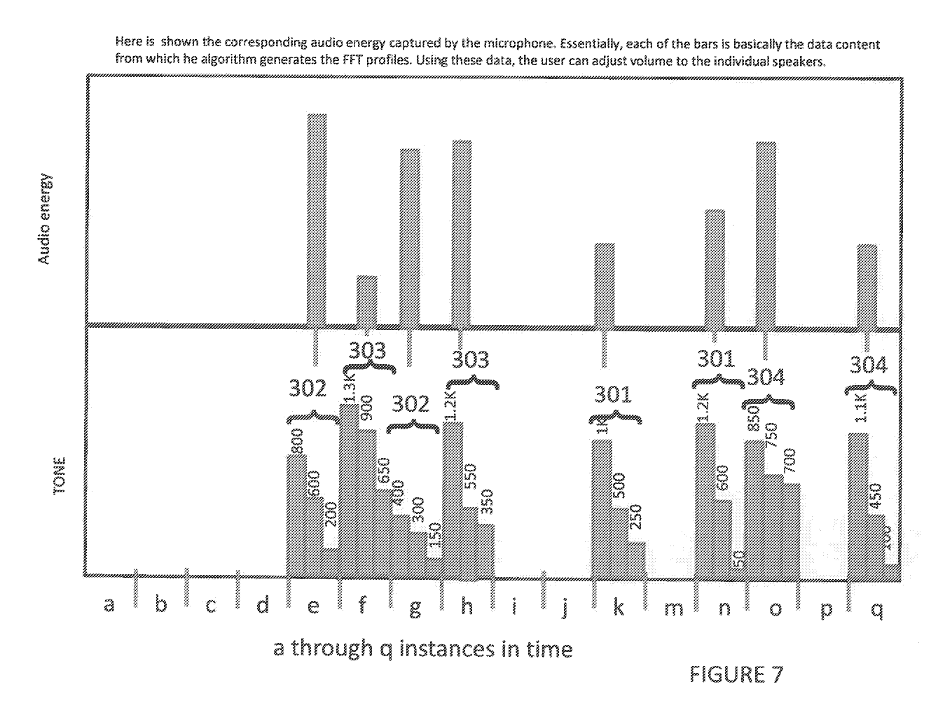

FIG. 7 shows an example audio energy captured by the microphone in FIG. 3. Each of the bars represents the data content from which the algorithm generates the FFT profiles. Using this data, the user can adjust volume to the individual speakers.

There have thus been described certain examples and embodiments of methods to calibrate an audio system. While embodiments have been described and disclosed, it will be appreciated that modifications of these embodiments are within the true spirit and scope of the invention. All such modifications are intended to be covered by the invention

As described herein, the methods described herein are not limited to any particular element(s) that perform(s) any particular function(s) and some steps of the methods presented need not necessarily occur in the order shown. For example, in some cases two or more method steps can occur in a different order or simultaneously. In addition, some steps of the described methods can be optional (even if not explicitly stated to be optional) and, therefore, can be omitted. These and other variations of the methods disclosed herein will be readily apparent, especially in view of the description of the method described herein, and are considered to be within the full scope of the invention.

Although features and elements are described above in particular combinations, each feature or element can be used alone without the other features and elements or in various combinations with or without other features and elements.

In view of the above, the foregoing merely illustrates the principles of the invention and it will thus be appreciated that those skilled in the art will be able to devise numerous alternative arrangements which, although not explicitly described herein, embody the principles of the invention and are within its spirit and scope. For example, although illustrated in the context of separate functional elements, these functional elements can be embodied in one, or more, integrated circuits (ICs). Similarly, although shown as separate elements, any or all of the elements can be implemented in a stored-program-controlled processor, e.g., a digital signal processor, which executes associated software, e.g., corresponding to one, or more, of the steps shown in, e.g., FIG. 1. It is therefore to be understood that numerous modifications can be made to the illustrative embodiments and that other arrangements can be devised without departing from the spirit and scope of the present invention as defined by the appended claims.

1. A method for calibrating audio for a plurality of speakers, comprising:
receiving a sample audio signal;
transmitting the sample audio signal to at least one speaker;
recording the sample audio signal from each speaker individually;
performing a fast Fourier (FFT) comparison of recorded sample audio signal temporally and volumetrically with the sample audio signal;
shifting a time delay for each speaker so that each of the plurality of speakers is synchronized;
comparing individual volumes of each speaker; and
adjusting individual volumes of each speaker to collectively match.

2. The method of claim 1, wherein a FFT profile is generated for each sample audio signal sent to the at least one speaker.

3. The method claim 1, wherein performing the FFT comparison includes:
sliding an individual FFT profile across a FFT profile of recorded audio from the plurality of speakers; and
determining correlation coefficients as the individual FFT profile slides across the FFT profile of recorded audio from the plurality of speakers.

4. The method of claim 3, wherein the time delay is based on the correlation coefficients.

5. The method of claim 1, wherein a FFT profile is generated for the recorded sample audio signal.

6. The method of claim 1, wherein the time delay accounts for delay differences present between an individual FFT profile and a FFT profile of recorded audio from the plurality of speakers.

7. The method of claim 1, wherein the time delay is shifted in given time increments.

8. An audio calibration system for calibrating a plurality of speakers, comprising:
a recording device configured to record a sample audio signal emanating from a speaker;
an audio calibration module configured to perform an FFT comparison of each recorded sample audio signal in terms of time and volume to the sample audio signal;
the audio calibration module is configured to shift a time delay for each speaker so that the plurality of speakers is synchronized; and
the audio calibration module is configured to compare individual volumes of each speaker or the audio calibration module is configured to adjust individual volumes of each speaker to match collectively.

9. The audio calibration system of claim 8, wherein a FFT profile is generated for each sample audio signal sent to the at least one speaker.

10. The audio calibration system of claim 8, wherein the audio calibration module is configured to slide an individual FFT profile across a FFT profile of recorded audio from the plurality of speakers and determine correlation coefficients as the individual FFT profile slides across the FFT profile of recorded audio from the plurality of speakers.

11. The audio calibration system of claim 10, wherein the time delay is based on the correlation coefficients.

12. The audio calibration system of claim 8, wherein a FFT profile is generated for the recorded sample audio signal.

13. The audio calibration system of claim 8, wherein the time delay accounts for delay differences present between an individual FFT profile and a FFT profile of recorded audio from the plurality of speakers.

14. The audio calibration system of claim 8, wherein the time delay is shifted in given time increments.

15. An audio calibration module for calibrating a plurality of speakers, comprising:
an audio calibration module configured to perform an FFT comparison of a recorded sample audio signal in terms of time and volume to a sample audio signal;
the audio calibration module is configured to shift a time delay for each speaker so that the plurality of speakers is synchronized;
the audio calibration module is configured to compare individual volumes of each speaker; and
the audio calibration module is configured to adjust individual volumes of each speaker to match collectively.

16. The audio calibration module of claim 15, wherein a FFT profile is generated for each sample audio signal sent to the at least one speaker.

17. The audio calibration module of claim 15, wherein the audio calibration module is configured to slide an individual FFT profile across a FFT profile of recorded audio from the plurality of speakers and determine correlation coefficients as the individual FFT profile slides across the FFT profile of recorded audio from the plurality of speakers.

18. The audio calibration module of claim 15, wherein the time delay is based on the correlation coefficients.

19. The audio calibration module of claim 15, wherein a FFT profile is generated for the recorded sample audio signal.

20. The audio calibration module of claim 15, wherein the time delay accounts for delay differences present between an individual FFT profile and a FFT profile of recorded audio from the plurality of speakers.
